(19) United States
(12) Patent Application Publication
(10) Pub. No.: US 2012/0088336 A1
(43) Pub. Date: Apr. 12, 2012

(54) SEMICONDUCTOR PACKAGE HAVING AN IMPROVED CONNECTION STRUCTURE AND METHOD FOR MANUFACTURING THE SAME

(75) Inventor: Tae Min KANG, Seoul (KR)

(73) Assignee: HYNIX SEMICONDUCTOR INC., Kyoungki-do (KR)

(21) Appl. No.: 13/329,937

(22) Filed: Dec. 19, 2011

Related U.S. Application Data
(62) Division of application No. 12/043,314, filed on Mar. 6, 2008, now abandoned.

(30) Foreign Application Priority Data
Jul. 27, 2007 (KR) 10-2007-0076022

(51) Int. Cl. H01L 21/50

(52) U.S. Cl. 438/121; 257/E21.499

(57) ABSTRACT

A semiconductor package having an improved connection structure and a method for manufacturing the same is described. The semiconductor package includes a substrate having a substrate body, connection pads that are located on one surface of the substrate body, and ball lands that are located on the other surface of the substrate body opposite the one surface. The ball lands are electrically connected to the connection pads. A semiconductor chip having bumps that are formed to correspond to the connection pads is connected to the substrate. An anisotropic conductive member having an insulation element is interposed between the substrate and the semiconductor chip to connect the substrate and the semiconductor chip. Electrically flowable conductive particles within the insulation element flow in the insulation element according to applied electric fields so as to arrange the electrically flowable conductive particles between the connection pads and the bumps.

### CROSS-REFERENCE TO RELATED APPLICATIONS

The present application claims priority to Korean patent application number 10-2007-0076022 filed on Jul. 27, 2007, which is incorporated herein by reference in its entirety.

### BACKGROUND OF THE INVENTION

The present invention relates to a semiconductor package and a method for manufacturing the same, and more particularly, to a semiconductor package that prevents a poor connection of the bonding pads of a semiconductor chip and the connection pads of a substrate.

Currently, semiconductor packages have been developed that include semiconductor devices that are capable of storing large amounts of data and processing such stored data quickly.

In general, semiconductor packages are manufactured through a semiconductor chip manufacturing process during which elements such as transistors, resistors, capacitors, and so forth, are integrated into a wafer to form semiconductor chips. A packaging process is also performed during which the semiconductor chips are parted from the wafer, electrically connected with outside circuit boards, etc., and are protected from externally applied shock and/or vibration due to the brittle nature of the semiconductor chips.

Semiconductor packages including semiconductor devices are widely used in personal computers, television receivers, electric home appliances, information and communication systems, and the like.

Recently, with the development of semiconductor packaging technologies, a flip chip package that has a size corresponding to 100% to 105% of the semiconductor chip size has been disclosed in the art.

A conventional flip chip package has a structure in which the bonding pads located on a semiconductor chip and the connection pads formed on a printed circuit board are electrically connected directly to each other using bumps instead of conductive wires.

The conventional flip chip package as described above is advantageous because it can store and/or process data at a high speed.

However, with the conventional flip chip package, it is necessary to separately implement an under-fill process for filling the gap formed between the semiconductor chip and the printed circuit board with an adhesive material or the like since the bonding pads of the semiconductor chip and the connection pads of the printed circuit board are electrically connected with each other using bumps.

Recently, another flip chip package has been developed which uses an anisotropic conductive film (ACF) including conductive balls and resin.

The flip chip package using an anisotropic conductive film has a structure where the bonding pads of a semiconductor chip and the connection pads of a printed circuit board are electrically connected with each other by the conductive balls and the resin fills the gap formed between the semiconductor chip and the printed circuit board. Therefore, it is not necessary to separately implement an under-fill process that is more advantageous than the conventional flip chip package.

Nevertheless, when electrically connecting the bonding pads of the semiconductor chip and the connection pads of the printed circuit board using the anisotropic conductive film, as the bonding pads are introduced into the resin of the anisotropic conductive film, the resin is squeezed by the bonding pads and flows aside. When the resin is squeezed by the bonding pads and flows aside, the conductive balls of the anisotropic conductive film also flow aside along with the resin. As a result, a poor electrical connection between the bonding pads of the semiconductor chip and the connection pads of the printed circuit board is likely.

### SUMMARY OF THE INVENTION

Embodiments of the present invention are directed to a semiconductor package that prevents a poor connection of the bonding pads of a semiconductor chip and the connection pads of a substrate.

Also, embodiments of the present invention are directed to a method for manufacturing the semiconductor package.

In one embodiment, a semiconductor package comprises a substrate having a substrate body, connection pads which are located on one surface of the substrate body, and ball lands which are located on the other surface of the substrate body, facing away from the one surface, and are electrically connected with the connection pads; a semiconductor chip having bumps which correspond to the connection pads; and an anisotropic conductive member having an insulation element which is interposed between the substrate and the semiconductor chip and electrically flowable conductive particles which flow in the insulation element by electric fields and are arranged between the connection pads and the bumps.

The electrically flowable conductive particles are present at a first density between the connection pads and the bumps and at a second density lower than the first density not between the connection pads and the bumps.

The electrically flowable conductive particles have first polarity parts having first polarity and/or second polarity parts having second polarity opposite the first polarity.

The insulation element contains an adhesive material.

In order to increase flowability of the electrically flowable conductive particles, the insulation element contains a synthetic resin material that decreases in viscosity by heat.

The electrically flowable conductive particles are regularly arranged between the connection pads and the bumps and are relatively irregularly arranged not between the connection pads and the bumps.

In another embodiment, a method for manufacturing a semiconductor package comprises the steps of preparing a substrate having a substrate body, connection pads which are located on one surface of the substrate body, and ball lands which are located on the other surface of the substrate body, facing away from the one surface, and are electrically connected with the connection pads; locating an anisotropic conductive member having electrically flowable conductive particles, which flow by electric fields, and an insulation element, on one surface of the substrate; inducing electric fields in the electrically flowable conductive particles through the connection pads, moving the electrically flowable conductive particles toward the connection pads in the insulation element, and rearranging the electrically flowable conductive particles; and electrically connecting bumps of a semiconductor chip with the connection pads using the electrically flowable conductive particles which are rearranged between the connection pads and the bumps.

The electrically flowable conductive particles have a first density at the connection pads and a second density lower than the first density not at the connection pads.

In the rearranging step, heat is applied to the anisotropic conductive member.

The electrically flowable conductive particles have first polarity parts having first polarity and/or second polarity parts having second polarity opposite the first polarity.

One of first power having first polarity and second power having second polarity opposite the first polarity is applied to each of the connection pads.

The first power is supplied to even-numbered connection pads, and the second power is applied to odd-numbered connection pads.

### BRIEF DESCRIPTION OF THE DRAWINGS

FIG. 1 is a cross-sectional view illustrating a semiconductor package in accordance with an embodiment of the present invention.

FIG. 2 is an enlarged view of section ‘A’ of FIG. 1.

FIGS. 3 through 7 are cross-sectional views illustrating a method of manufacturing a semiconductor package in accordance with another embodiment of the present invention.

### DESCRIPTION OF SPECIFIC EMBODIMENTS

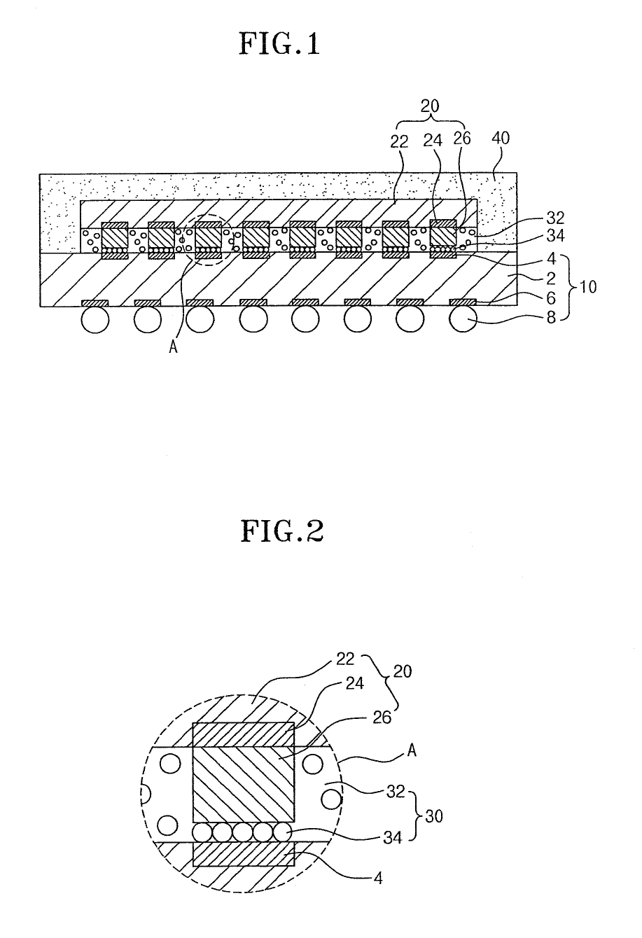

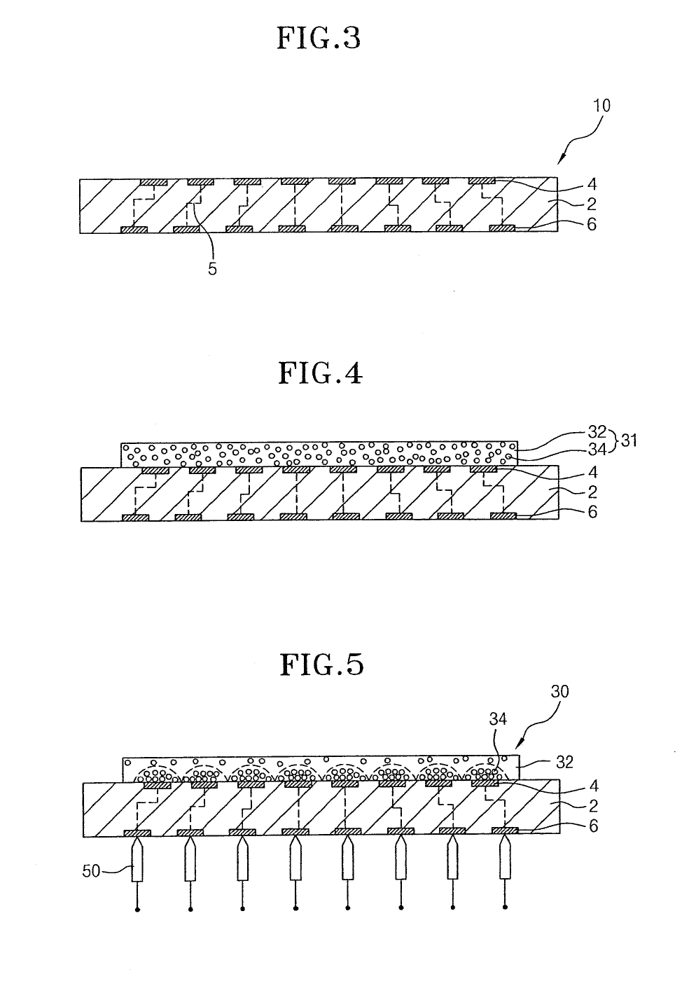

FIG. 1 is a cross-sectional view illustrating a semiconductor package in accordance with an embodiment of the present invention. FIG. 2 is an enlarged view of the section ‘A’ labeled in FIG. 1.

Referring to FIGS. 1 and 2, a semiconductor package includes a substrate 10, a semiconductor chip 20, and an anisotropic conductive member 30. In addition, the semiconductor package can selectively include a molding member 40.

The substrate 10 includes a substrate body 2, connection pads 4, ball lands 6, and conductive balls 8.

The substrate body 2 has, for example, has a plate shape and includes at least one-layered circuit pattern (not shown). The substrate body 2 can, for example, be a printed circuit board.

The connection pads 4 are located on one surface of the substrate body 2. The ball lands 6 are located on the surface of the substrate body 2 opposite the surface having the connection pads 4. The respective connection pads 4 and the respective ball lands 6 are electrically connected to each other via the circuit pattern of the substrate body 2.

The conductive balls 8 are electrically connected with the ball lands 6. The conductive balls 8 can, for example, be solder balls containing solder.

The semiconductor chip 20 includes a semiconductor chip body 22, bonding pads 24, and bumps 26.

The semiconductor chip body 22 includes a data storage section (not shown) for storing data and a data processing section (not shown) for processing data.

The bonding pads 24 are located on the semiconductor chip body 22 and are electrically connected with the data storage section and/or the data processing section. The bonding pads 24 can be formed of aluminum or aluminum alloy having excellent electrical characteristics.

The bumps 26 are electrically connected, for example, with the bonding pads 24. In the present embodiment of the present invention, the bumps 26 can be stud bumps that project the bonding pads 24. The bumps 26 are formed such that their position corresponds to the connection pads 4 formed on the substrate body 2.

The anisotropic conductive member 30 has, for example, a film shape. The anisotropic conductive member 30 includes an insulation element 32 and electrically Plowable conductive particles 34.

For example, the insulation element 32 can be formed of a synthetic resin material whose viscosity and flowability is controlled by heat. The insulation element 32 contains an adhesive material for securing the substrate 10 and the semiconductor chip 20 to each other.

The electrically flowable conductive particles 34 are included in the insulation element 32. The electrically flowable conductive particles 34 have a characteristic in that they are rearranged in the insulation element 32 by electric or magnetic fields.

The electrically flowable conductive particles 34 have polarities in order to allow the electrically flowable conductive particles 34 to be rearranged in the insulation element 32 according to applied electric fields.

Each of the electrically flowable conductive particles 34 may possess a first polarity part having a first polarity such as a positive polarity. Each of the electrically flowable conductive particles 34 may possess a second polarity part having a second polarity that is opposite the first polarity such as a negative polarity. In addition, each of the electrically flowable conductive particles 34 may possess both the first polarity part having the first polarity and the second polarity part having the second polarity.

The electrically flowable conductive particles 34 having polarities included in the insulation element 32 of the anisotropic conductive member 30 flow in the insulation element 32 according to electric fields and are concentrated between the connection pads 4 of the substrate 10 and the bumps 26 of the semiconductor chip 20.

Where the electrically flowable conductive particles 34 having polarities in the insulation element 32 are concentrated between the connection pads 4 and the bumps 26 according to electric fields, the electrically flowable conductive particles 34 are present at a higher first density between the connection pads 4 and the bumps 26 and at a lower second density not between the connection pads 4 and the bumps 26. Accordingly, it is possible to prevent a poor electrical connection between the bumps 26 and the connection pads 4 that may occur while the bumps 26 and the connection pads 4 are electrically and physically coupled to each other by the electrically flowable conductive particles 34.

Also, the electrically flowable conductive particles 34 are more uniformly placed between the connection pads 4 and the bumps 26 than the area not between the connection pads 4 and the bumps 26 due to the fact that the electrically flowable conductive particles 34 having polarities in the insulation element 32 are concentrated between the connection pads 4 and the bumps 26 according to electric fields. Hence, it is possible to prevent a poor electrical connection between the bumps 26 and the connection pads 4 that may occur while the bumps 26 and the connection pads 4 are electrically and physically coupled to each other by the electrically flowable conductive particles 34.

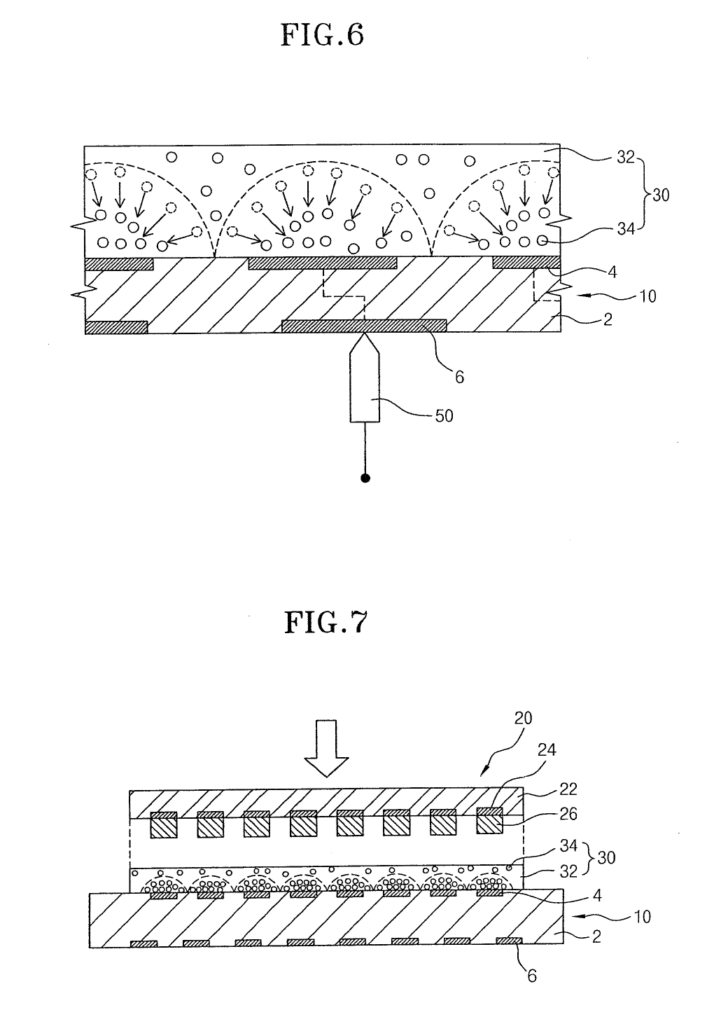

FIGS. 3 through 7 are cross-sectional views illustrating a method of manufacturing a semiconductor package in accordance with another embodiment of the present invention.

Referring to FIG. 3, in order to manufacture a semiconductor package, a substrate 10 is first prepared.

The substrate 10 having a plate shape has a substrate body 2. Connection pads 4 are formed on a first surface of the substrate body 2. Ball lands 6 are electrically connected to the connection pads 4 by conductive vias 5 and the like, and are formed on a second surface of the substrate body 2 opposite the first surface.

Referring to FIG. 4, after the substrate 10 is prepared, a preliminary anisotropic conductive member 31 is attached to the first surface of the substrate body 2 of the substrate 10.

The preliminary anisotropic conductive member 31 includes an insulation element 32 and electrically flowable conductive particles 34 that are placed in the insulation element 32.

In the present embodiment, the insulation element 32 may be formed of synthetic resin having an insulation property and a physical characteristic whereby viscosity is determined by heat. In addition, the insulation element 32 contains an adhesive material for securing the substrate 10 and a semiconductor chip to be described later, to each other.

The electrically flowable conductive particles 34 flow in the insulation element 32 according to electric fields and are rearranged in the insulation element 32. The electrically flowable conductive particles 34 possess first polarity parts having a first polarity. The electrically flowable conductive particles 34 may possess second polarity parts having the second polarity that is opposite the first polarity. In addition, the electrically flowable conductive particles 34 may possess both first polarity parts having the first polarity and second polarity parts having the second polarity. In the present embodiment, the first polarity may be a positive polarity and the second polarity may be a negative polarity.

The electrically flowable conductive particles 34 are randomly placed in the insulation element 32 of the preliminary anisotropic conductive member 31.

Referring to FIGS. 5 and 6, after the preliminary anisotropic conductive member 31 is attached to the connection pads 4 of the substrate body 2, electric fields are applied to the electrically flowable conductive particles 34 of the preliminary anisotropic conductive member 31 so that the electrically flowable conductive particles 34 are rearranged.

The electrically flowable conductive particles 34 of the preliminary anisotropic conductive member 31 may possess first polarity parts having the positive polarity to allow the electrically flowable conductive particles 34 to be rearranged. When the electrically flowable conductive particles 34 have the positive polarity, power is supplied from power supply members 50 having the negative polarity to the ball lands 6 that are electrically connected to the connection pads 4.

When power having a negative polarity is supplied to the connection pads 4 via the ball lands 6, the electrically flowable conductive particles 34 possessing the first polarity parts having the positive polarity flow towards the connection pads 4 by an attractive force. As a result, the anisotropic conductive member 30 is formed having rearranged electrically flowable conductive particles 34.

During this process, in order to ensure that the electrically flowable conductive particles 34 can easily flow towards the connection pads 4, the preliminary anisotropic conductive member 31 may be heated to a predetermined temperature to decrease the viscosity of the insulation element 32.

The rearranged electrically flowable conductive particles 34 have a higher first density at the connection pads 4 and a lower second density not at the connection pads 4. The electrically flowable conductive particles 34 having the first density at the connection pads 4 are rearranged relatively regularly.

Meanwhile, in order to allow the electrically flowable conductive particles 34 to be rearranged, the electrically flowable conductive particles 34 included in the preliminary anisotropic conductive member 31 may possess second polarity parts having a negative polarity. When the electrically flowable conductive particles 34 have the negative polarity, power is supplied from power supply members 50 and having the positive polarity is applied to the ball lands 6 that are electrically connected to the connection pads 4.

When power having the positive polarity is supplied to the connection pads 4 via the ball lands 6, the electrically flowable conductive particles 34 possessing the second polarity parts having the negative polarity flow towards the connection pads 4 by an attractive force. As a result, the anisotropic conductive member 30 is formed having the rearranged electrically flowable conductive particles 34.

During this process, in order to ensure that the electrically flowable conductive particles 34 are easily flow towards the connection pads 4, the preliminary anisotropic conductive member 31 may be heated to a predetermined temperature to decrease the viscosity of the insulation element 32.

The rearranged electrically flowable conductive particles 34 have a higher first density at the connection pads 4 and a lower second density not at the connection pads 4. The electrically flowable conductive particles 34 having the first density at the connection pads 4 are rearranged relatively regularly.

Further, the electrically flowable conductive particles 34 included in the preliminary anisotropic conductive member 31 may possess both first polarity parts having the positive polarity and second polarity parts having the negative polarity in order to allow the electrically flowable conductive particles 34 to be rearranged.

When power is supplied from power supply members 50 having a positive polarity and a negative polarity to the ball lands 6 that are electrically connected to the connection pads 4, the electrically flowable conductive particles 34 flow towards the connection pads 4 by an attractive force. As a result the anisotropic conductive member 30 is formed having the rearranged electrically flowable conductive particles 34.

During this time, in order to ensure that the electrically flowable conductive particles 34 can easily flow towards the connection pads 4, the preliminary anisotropic conductive member 31 may be heated to a predetermined temperature to decrease the viscosity of the insulation element 32.

The rearranged electrically flowable conductive particles 34 have a higher first density at the connection pads 4 and a lower second density not at the connection pads 4. The electrically flowable conductive particles 34 having the first density at the connection pads 4 are rearranged relatively regularly.

When the electrically flowable conductive particles 34 possess both the first polarity parts and the second polarity parts, power having the negative polarity can be supplied to an even number of connection pads 4 and power having the positive polarity can be supplied to an odd number of connection pads 4. As a result, the electrically flowable conductive particles 34 that have flowed to each of the connection pads 4 may have a shape of a semicircle at the respective connection pads 4 in the insulation element 32.

Referring to FIG. 7, a semiconductor chip 20 is attached to the anisotropic conductive member 30 after the anisotropic conductive member 30 having the rearranged electrically flowable conductive particles 34 has been attached to the substrate 10.

The semiconductor chip 20 includes a semiconductor chip body 22, bonding pads 24, and bumps 26. At this time, the bonding pads 24 of the semiconductor chip 20 are formed to correspond to the connection pads 4 formed on the substrate 10. The bumps 26 are electrically connected to the bonding pads 24.

The bumps 26 are introduced into the anisotropic conductive member 30 in which the electrically flowable conductive particles 34 are rearranged. The bumps 26 are introduced such that the bumps 26, the electrically flowable conductive particles 34, and the connection pads 4 are electrically and physically connected to one another.

As is apparent from the above description, in the present invention, electrically flowable conductive particles that can be rearranged according to an electric field are included in an anisotropic conductive member. By applying electric fields to connection pads, the electrically flowable conductive particles may be rearranged in the anisotropic conductive member. As a result, a poor electrical connection between the connection pads and the bumps of a semiconductor chip can be prevented.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a semiconductor package, comprising the steps of:
preparing a substrate having a substrate body, connection pads located on a first surface of the substrate body, and ball lands located on a second surface of the substrate body opposite the first surface that are electrically connected with the connection pads;
locating an anisotropic conductive member on the first surface of the substrate, the anisotropic conductive material having electrically flowable conductive particles and an insulation element;
applying electric fields to the electrically flowable conductive particles through the connection pads to move the electrically flowable conductive particles towards the connection pads within the insulation element in order to rearrange the electrically flowable conductive particles; and
electrically connecting bumps of a semiconductor chip to the connection pads using the electrically flowable conductive particles that are rearranged between the connection pads and the bumps.

2. The method according to claim 1, wherein the electrically flowable conductive particles comprise a first density at the connection pads and a second density in an area not at the connection pads,
wherein the second density is lower than the first density.

3. The method according to claim 1, wherein in the step of applying electric fields and rearranging the electrically flowable conductive particles, heat is applied to the anisotropic conductive member.

4. The method according to claim 1, wherein the electrically flowable conductive particles comprise first polarity parts having a first polarity and/or second polarity parts having a second polarity opposite the first polarity.

5. The method according to claim 4, wherein one of a first power having the first polarity or a second power having the second polarity that is opposite the first polarity is applied to each of the connection pads.

6. The method according to claim 4, wherein the first power is supplied to even-numbered connection pads and the second power is applied to odd-numbered connection pads.
